(19) United States
(12) Patent Application Publication
(10) Pub. No.: US 2019/0356270 A1
(43) Pub. Date: Nov. 21, 2019

(54) POWER OSCILLATOR USING GaN POWER AMPLIFIER

(71) Applicant: WAVEPIA CO., LTD., Gyeonggi-do (KR)

(72) Inventor: Sang-Hun LEE, Gyeonggi-do (KR)

(21) Appl. No.: 16/389,139

(22) Filed: Apr. 19, 2019

(30) Foreign Application Priority Data
May 18, 2018 (KR) 10-2018-057089

(51) Int. Cl. H03B 5/12; H03F 3/20; H03F 1/02; H03F 1/56; H03H 7/38; H03H 7/46

(52) U.S. Cl. CPC H03B 5/1225; H03F 3/20; H03H 7/463; H03F 1/56; H03H 7/38; H03F 1/0277

(57) ABSTRACT

A power oscillator using a GaN power amplifier, includes: the GaN power amplifier configured of a gallium nitride (GaN) element to amplify and output power of an input signal; a directional coupler for providing part of an output signal of the GaN power amplifier as a feedback signal; a phase shifter for changing a phase of the feedback signal provided by the directional coupler; and a first isolator for adjusting impedance mismatching generated by the phase shifter and transferring the feedback signal to the GaN power amplifier.

### BACKGROUND

The present invention relates to a power oscillator using a GaN power amplifier, and more specifically, to a power oscillator using a high-power high-efficiency GaN power amplifier, which includes a gallium nitride (GaN) element, and a feedback loop.

Owing to expansion of Information and Communications Technologies (ICT), various activities performed in outdoor spaces are performed indoor gradually. Accordingly, the proportion of indoor space in everyday life is gradually increasing, and services provided targeting outdoor space such as navigation and the like are expanded targeting the indoor space.

To satisfy such a service demands, radio frequency (RF) products providing high-performance are proposed, and a high-power high-efficiency power oscillator is essential for the high-performance RF products.

Conventionally, a cascade-type power amplifier should be added to the outside to implement the high-power high-efficiency power oscillator.

The background techniques of the present invention are disclosed in Korean Laid-opened Patent No. 10-2012-0128370.

### SUMMARY OF THE INVENTION

Therefore, the present invention has been made in view of the above problems, and it is an object of the present invention to provide a power oscillator using a high-power high-efficiency GaN power amplifier, which includes a gallium nitride (GaN) element, and a feedback loop.

The problems to be solved by the present invention are not limited to those mentioned above, and unmentioned other problems may be clearly understood by those skilled in the art from the following descriptions.

To accomplish the above object, according to one aspect of the present invention, there is provided a power oscillator using a GaN power amplifier, the power oscillator including: the GaN power amplifier configured of a gallium nitride (GaN) element to amplify and output power of an input signal; a directional coupler for providing part of an output signal of the GaN power amplifier as a feedback signal; a phase shifter for changing a phase of the feedback signal provided by the directional coupler; and a first isolator for adjusting impedance mismatching generated by the phase shifter and transferring the feedback signal to the GaN power amplifier.

The power oscillator using a GaN power amplifier according to an embodiment of the present invention preferably further includes an attenuator disposed between the directional coupler and the phase shifter to change magnitude of the feedback signal provided by the directional coupler.

The power oscillator using a GaN power amplifier according to an embodiment of the present invention preferably further includes a second isolator disposed between the directional coupler and an output terminal to adjust impedance mismatching generated by the directional coupler.

To accomplish the above object, according to another aspect of the present invention, there is provided apower oscillator using a GaN power amplifier, the power oscillator including: a first GaN power amplifier configured of a gallium nitride (GaN) element to amplify and output power of an input signal; a second GaN power amplifier configured of a gallium nitride (GaN) element and connected to the first GaN power amplifier in parallel to amplify and output power of an input signal; a power combiner for combining signals amplified and outputted by the first GaN power amplifier and the second GaN power amplifier; a directional coupler for providing part of the signal transferred by the power combiner as a feedback signal; a phase shifter for changing a phase of the feedback signal provided by the directional coupler; a first isolator for adjusting impedance mismatching generated by the phase shifter; and a power splitter for splitting the feedback signal transferred through the first isolator and transferring the split feedback signals to the first GaN power amplifier and the second GaN power amplifier.

The power oscillator using a GaN power amplifier according to another embodiment of the present invention preferably further includes an attenuator disposed between the directional coupler and the phase shifter to change magnitude of the feedback signal provided by the directional coupler.

The power oscillator using a GaN power amplifier according to another embodiment of the present invention preferably further includes a second isolator disposed between the directional coupler and an output terminal to adjust impedance mismatching generated by the directional coupler.

### BRIEF DESCRIPTION OF THE DRAWINGS

FIG. 1 is a circuit diagram showing a power oscillator using a GaN power amplifier according to an embodiment of the present invention.

FIG. 2 is a circuit diagram showing a power oscillator using a GaN power amplifier according to another embodiment of the present invention.

### DETAILED DESCRIPTION OF THE PREFERRED EMBODIMENT

The detailed description of the present invention described below with reference to the accompanying drawings which show specific embodiments embodied by the present invention as an example. These embodiments are described in detail as sufficiently as to be embodied by those skilled in the art. It should be understood that the diverse embodiments of the present invention are different from each other, but do not need to be mutual exclusive. For example, the specific configurations, structures and features disclosed herein may be implemented as another embodiment without departing from the spirit and scope of the present invention in relation to an embodiment. In addition, it should be understood that the positions and arrangements of individual components in each disclosed embodiment may be changed without departing from the spirit and scope of the present invention.

Accordingly, the detailed description described below is not to be taken as a restrictive meaning, but the scope of the present invention, if properly described, is only restricted by the appended claims and all the scope equivalent to those of the claims. In the drawings, similar reference symbols denote the same or similar functions throughout various aspects, and the length, area, thickness and the like and the shape may be exaggerated for convenience.

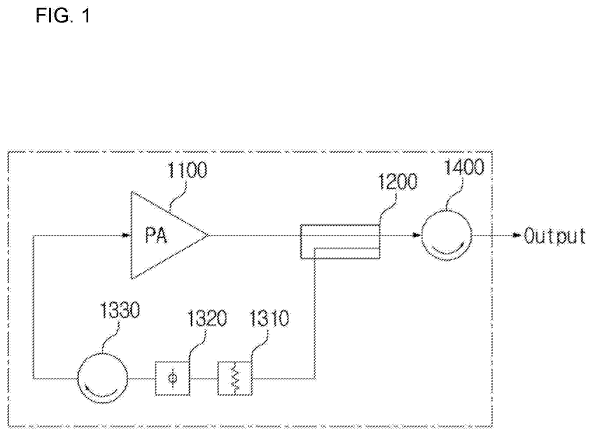

A power oscillator using a GaN power amplifier according to an embodiment of the present invention may be configured to include a GaN power amplifier 1100, a directional coupler 1200, a phase shifter 1320 and a first isolator 1330, as shown in FIG. 1.

Here, the GaN power amplifier 1100 is configured of a gallium nitride (GaN) element and amplifies and outputs power of an input signal, and the directional coupler 1200 provides part of an output signal of the GaN power amplifier 1100 as a feedback signal.

In addition, the phase shifter 1320 changes the phase of the feedback signal provided by the directional coupler 1200, and the first isolator 1330 transfers the feedback signal to the GaN power amplifier 1100 and adjusts impedance mismatching generated by the phase shifter 1320.

Meanwhile, the power oscillator using a GaN power amplifier according to an embodiment of the present invention further includes an attenuator 1310 disposed between the directional coupler 1200 and the phase shifter 1320 to change magnitude of the feedback signal provided by the directional coupler 1200.

In addition, the power oscillator using a GaN power amplifier according to an embodiment of the present invention further includes a second isolator 1400 disposed between the directional coupler 1200 and an output terminal to adjust impedance mismatching generated by the directional coupler 1200.

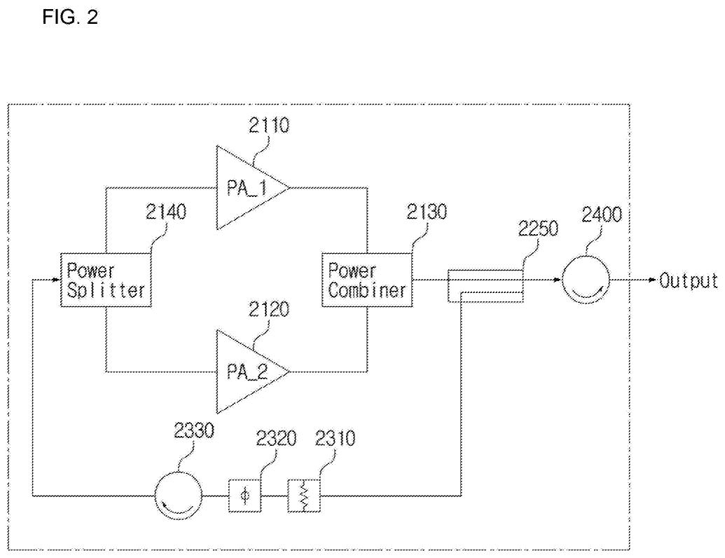

A power oscillator using a GaN power amplifier according to another embodiment of the present invention may be configured to include a first GaN power amplifier 2110, a second GaN power amplifier 2120, a power combiner 2130, a directional coupler 2200, a phase shifter 2320, a first isolator 2330 and a power splitter 2140, as shown in FIG. 2.

Here, the first GaN power amplifier 2110 is configured of a gallium nitride (GaN) element and amplifies and outputs power of an input signal, and the second GaN power amplifier 2120 is configured of a gallium nitride (GaN) element and connected to the first GaN power amplifier 2110 in parallel and amplifies and outputs power of an input signal, and the power combiner 2130 combines signals amplified and outputted by the first GaN power amplifier 2110 and the second GaN power amplifier 2120.

In addition, the directional coupler 2200 provides part of the signal transferred by the power combiner 2130 as a feedback signal, and the phase shifter 2320 changes the phase of the feedback signal provided by the directional coupler 2200.

Meanwhile, the first isolator 2330 adjusts impedance mismatching generated by the phase shifter 2320, and the power splitter 2140 splits the feedback signal transferred through the first isolator 2330 and transfers the split feedback signals to the first GaN power amplifier 2110 and the second GaN power amplifier 2120.

The power oscillator using a GaN power amplifier according to another embodiment of the present invention further includes an attenuator 2310 disposed between the directional coupler 2200 and the phase shifter 2320 to change magnitude of the feedback signal provided by the directional coupler 2200.

In addition, the power oscillator using a GaN power amplifier according to another embodiment of the present invention further includes a second isolator 2400 disposed between the directional coupler 2200 and an output terminal to adjust impedance mismatching generated by the directional coupler 2200.

The power oscillator using a GaN power amplifier according to the embodiments of the present invention may provide a high-power high-efficiency power signal using a GaN power amplifier, which includes a gallium nitride (GaN) element, and a feedback loop.

Although the present invention has been described and shown in relation to the preferred embodiments for illustrating the principle of the present invention, the present invention is not limited to the configuration and action as is shown and described.

Rather, those skilled in the art may fully understand that the present invention can be diversely changed and modified without departing from the spirit and scope of the appended claims.

Accordingly, all proper changes, modifications and equivalents should be regarded as being included in the scope of the present invention.

What is claimed is:

1. A power oscillator using a GaN power amplifier, the power oscillator comprising:
The GaN power amplifier configured of a gallium nitride (GaN) element to amplify and output power of an input signal;
A directional coupler for providing part of an output signal of the GaN power amplifier as a feedback signal;
A phase shifter for changing a phase of the feedback signal provided by the directional coupler; and
a first isolator for adjusting impedance mismatching generated by the phase shifter and transferring the feedback signal to the GaN power amplifier.

2. The power oscillator according to claim 1, further comprising an attenuator disposed between the directional coupler and the phase shifter to change magnitude of the feedback signal provided by the directional coupler.

3. The power oscillator according to claim 1, further comprising a second isolator disposed between the directional coupler and an output terminal to adjust impedance mismatching generated by the directional coupler.

4. A power oscillator using a GaN power amplifier, the power oscillator comprising:
a first GaN power amplifier configured of a gallium nitride (GaN) element to amplify and output power of an input signal;
a second GaN power amplifier configured of a gallium nitride (GaN) element and connected to the first GaN power amplifier in parallel to amplify and output power of an input signal;
a power combiner for combining signals amplified and outputted by the first GaN power amplifier and the second GaN power amplifier;
a directional coupler for providing part of the signal transferred by the power combiner as a feedback signal;
a phase shifter for changing a phase of the feedback signal provided by the directional coupler;
a first isolator for adjusting impedance mismatching generated by the phase shifter; and
a power splitter for splitting the feedback signal transferred through the first isolator and transferring the split feedback signals to the first GaN power amplifier and the second GaN power amplifier.

5. The power oscillator according to claim 4, further comprising an attenuator disposed between the directional coupler and the phase shifter to change magnitude of the feedback signal provided by the directional coupler.

6. The power oscillator according to claim 4, further comprising a second isolator disposed between the directional coupler and an output terminal to adjust impedance mismatching generated by the directional coupler.
